(19) United States
(12) Patent Application Publication
(10) Pub. No.: US 2015/0262631 A1
(43) Pub. Date: Sep. 17, 2015

(54) SEMICONDUCTOR MEMORY DEVICE

(71) Applicant: Naoki SHIMIZU, Seoul (KR)

(72) Inventor: Naoki SHIMIZU, Seoul (KR)

(21) Appl. No.: 14/482,925

(22) Filed: Sep. 10, 2014

Related U.S. Application Data
(60) Provisional application No. 61/951,433, filed on Mar. 11, 2014.

(51) Int. Cl. G11C 7/10; G11C 5/06; G11C 14/00

(52) U.S. Cl. CPC G11C 7/1072; G11C 14/0045; G11C 14/0081; G11C 5/066; G11C 14/0036; G11C 14/009; G11C 13/0004

(57) ABSTRACT

According to one embodiment, there is provided a semiconductor memory device comprising: a memory cell array including a plurality of memory cells configured to be able to store data; a control circuit configured to control a write operation of data in the memory cell array, and an initialization operation of the memory cell array; and a register control circuit configured to receive a first command including second information for selecting first information relating to control of a cycle of a clock from completion of the write operation of data in the memory cell array to initialization of the memory cell array.

### CROSS REFERENCE TO RELATED APPLICATIONS

This application claims the benefit of U.S. Provisional Application No. 61/951,433, filed Mar. 11, 2014, the entire contents of which are incorporated herein by reference.

### FIELD

Embodiments described herein relate generally to a semiconductor memory device.

### BACKGROUND

An MRAM (Magnetic Random Access Memory) is a memory device using a magnetic element having a magnetoresistive effect for a memory cell which stores information, and attention has been paid to the MRAM as a next-generation memory device characterized by a high-speed operation, a large capacity and nonvolatility. In addition, MRAMs have been vigorously researched and developed as substitutes for volatile memories such as DRAMs and SRAMs. In this case, it is desirable to operate the MRAMs with the same specifications as the DRAMs and SRAMs, in order to suppress development costs and to smoothly substitute the MRAMs.

### BRIEF DESCRIPTION OF THE DRAWINGS

FIG. 1 is a block diagram illustrating a basic configuration of a semiconductor memory device according to a first embodiment.

FIG. 2 is a circuit diagram illustrating a basic configuration of a memory cell array according to the first embodiment.

FIG. 3 is a view illustrating information included in a mode register write command according to the first embodiment.

FIG. 4 is a view illustrating information included in the mode register write command according to the first embodiment.

FIG. 5 is a block diagram illustrating a basic configuration of a mode register control circuit according to the first embodiment.

FIG. 6 is a view illustrating a basic configuration of a switch circuit according to the first embodiment.

FIG. 7 is a table which is set in a multiplexer according to the first embodiment.

FIG. 8 is a view illustrating a write cycle according to the first embodiment.

FIG. 9 is a view illustrating information included in a mode register write command according to a second embodiment.

FIG. 10 is a view illustrating information included in the mode register write command according to the second embodiment.

FIG. 11 is a block diagram illustrating a basic configuration of a mode register control circuit according to the second embodiment.

FIG. 12 is a table which is set in a multiplexer according to the second embodiment.

FIG. 13 is a table which is set in a multiplexer according to a modification.

FIG. 14 is a table which is set in a multiplexer according to a modification.

### DETAILED DESCRIPTION

In general, according to one embodiment, there is provided a semiconductor memory device comprising: a memory cell array including a plurality of memory cells configured to be able to store data; a control circuit configured to control a write operation of data in the memory cell array, and an initialization operation of the memory cell array; and a register control circuit configured to receive a first command including second information for selecting first information relating to control of a cycle of a clock from completion of the write operation of data in the memory cell array to initialization of the memory cell array, and to output, when receiving, following the first command, a second command including third information for selecting the first information, the first information to the control circuit, based on the second information and the third information.

Hereinafter, embodiments will be described with reference to the accompanying drawings. In the description below, structural elements having substantially the same functions and structures are denoted by like reference signs, and an overlapping description is given only where necessary. Besides, embodiments to be described below illustrate, by way of example, devices or methods for embodying technical concepts of the embodiments, and the technical concepts of the embodiments do not specifically restrict the material, shape, structure, arrangement, etc. of structural components to those described below. Various changes may be made in the technical concepts of the embodiments within the scope of the claims.

Each of functional blocks can be realized as hardware, computer software, or a combination of both. Thus, each block will be described below, in general, from the standpoint of the function thereof, so as to make it clear that each block is any one of hardware, computer software, or a combination of both. Whether such a function is implemented as hardware or implemented as software depends on design restrictions which are imposed on a specific embodiment or the entire system. A person skilled in the art may realize these functions by various methods in each of specific embodiments, and to determine such realization is within the scope of the present invention.

In each of the embodiments to be described below, an MRAM (Magnetic Random Access Memory) is described as an example of the semiconductor memory device.

### First Embodiment

### Outline of a Semiconductor Memory Device

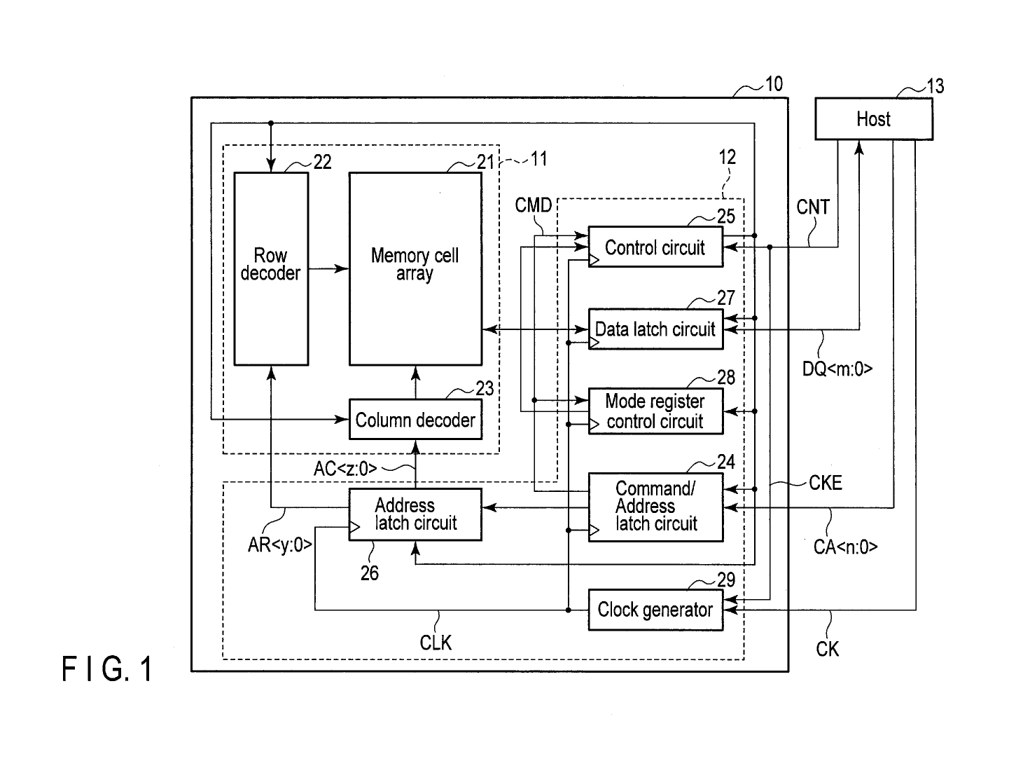

To begin with, referring to FIG. 1, a semiconductor memory device 10 according to a first embodiment is described.

As illustrated in FIG. 1, the semiconductor memory device 10 includes a memory core 11 and a peripheral circuit 12.

The memory core 11 includes a memory cell array 21, a row decoder 22 and a column decoder 23.

The memory cell array 21 is an MRAM, in which a plurality of memory cells MC are arranged two-dimensionally in a matrix. A plurality of word lines WL are arranged in a row direction and a plurality of bit lines BL are arranged in a column direction such that the word lines WL and bit lines BL cross each other. Two neighboring bit lines BL constitute a pair, and the memory cell MC is provided in association with an intersection between the word line WL and the bit line pair (in this embodiment, for convenience′ sake, referred to as a bit line BL and a source line SL).

The row decoder 22 is connected to the word lines of the memory cell array 21. In addition, the row decoder 22 decodes a row address AR<y:0> for selecting a row in the memory cell array 21, which is supplied from a command/address latch circuit 24. Besides, the row decoder 22 includes a word line driver. The word line driver is configured so as to apply a voltage to a selected word line WL at a time of data read or data write. To be more specific, the word line driver is configured so as to be able to apply a voltage to a selected word line WL in accordance with a decoded row address.

The column decoder 23 is connected to the bit line pairs of the memory cell array 21. In addition, the column decoder 23 decodes a column address AC<z:0> for selecting a column in the memory cell array 21, which is supplied from the command/address latch circuit 24.

The peripheral circuit 12 executes data write and data read in/from the memory core 11. In addition, the peripheral circuit 12 receives from a host 13 a control signal CNT for read/write, and a clock CK for controlling an operation timing of read/write. Furthermore, the peripheral circuit 12 is connected to the host by a command/address line CA<n:0> and a data line DQ<m:0>. In this case, n and m are natural numbers.

The control signal CNT includes a clock enable signal CKE and a chip select signal CS. The clock CK is used in order to control the operation timing of the semiconductor memory device 10. The command/address line CA<n:0> is used for transmission/reception of a command and address. The data line DQ<m:0> is used for transmission/reception of input data and output data.

The peripheral circuit 12 includes a command/address latch circuit 24, a control circuit 25, an address latch circuit 26, a data latch circuit 27, a mode register control circuit 28, and a clock generator 29.

The command/address latch circuit 24 receives a command CMD and an address ADD from the host 13 via the command/address line CA<n:0, and temporarily stores the command CMD and address ADD. The command/address latch circuit 24 delivers the command CMD to the control circuit 25, and sends the address ADD to the address latch circuit 26.

The control circuit 25 controls the internal operation of the semiconductor memory device 10, based on the control signal CNT and command CMD from the host 13.

The address latch circuit 26 latches the address ADD, sends a row address AR<y:0> to the row decoder 22, and sends a column address AC<z:0> to the column decoder 23.

The data latch circuit 27 temporarily stores input data which has been input from the host 13 via the data line DQ<m:0>, or output data which has been read out from a selected bank. The input data is written in the memory cell array 21.

The mode register control circuit 28 includes a plurality of registers in which information relating to the operation of the semiconductor memory device 10 is stored. The details of the mode register control circuit 28 will be described later.

The clock generator 29 generates an internal clock CLK, based on the clock CK from the host 13. The internal clock CLK is input to the command/address latch circuit 24, control circuit 25, address latch circuit 26, data latch circuit 27 and mode register control circuit 28, and is used in order to control the operation timings thereof.

<Memory Cell Array>

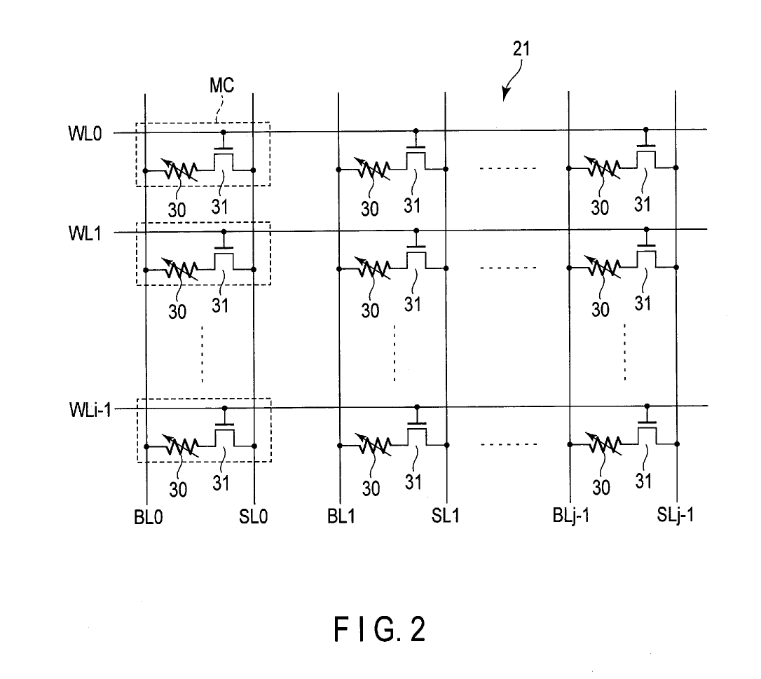

Next, referring to FIG. 2, a description is given of the structure of the memory cell array 21 according to the first embodiment. As described above, the memory cell array 21 is configured such that a plurality of memory cells MC are arranged in a matrix. In the memory cell array 21, a plurality of word lines WL0 to WLi−1, a plurality of bit lines BL0 to BLj−1, and a plurality of source lines SL0 to SLj−1 are disposed. One row of the memory cell array is connected to one word line WL, and one column of the memory cell array is connected to a pair composed of one bit line BL and one source line SL.

The memory cell MC is composed of an MTJ (Magnetic Tunnel Junction) element 30 and a select transistor 31. The select transistor 31 is composed of, for example, an N-channel MOSFET.

One end of the MTJ element 30 is connected to the bit line BL, and the other end of the MTJ element 30 is connected to the drain of the select transistor 31. The gate of the select transistor 31 is connected to the word line WL, and the source thereof is connected to the source line SL.

<Command MRW1>

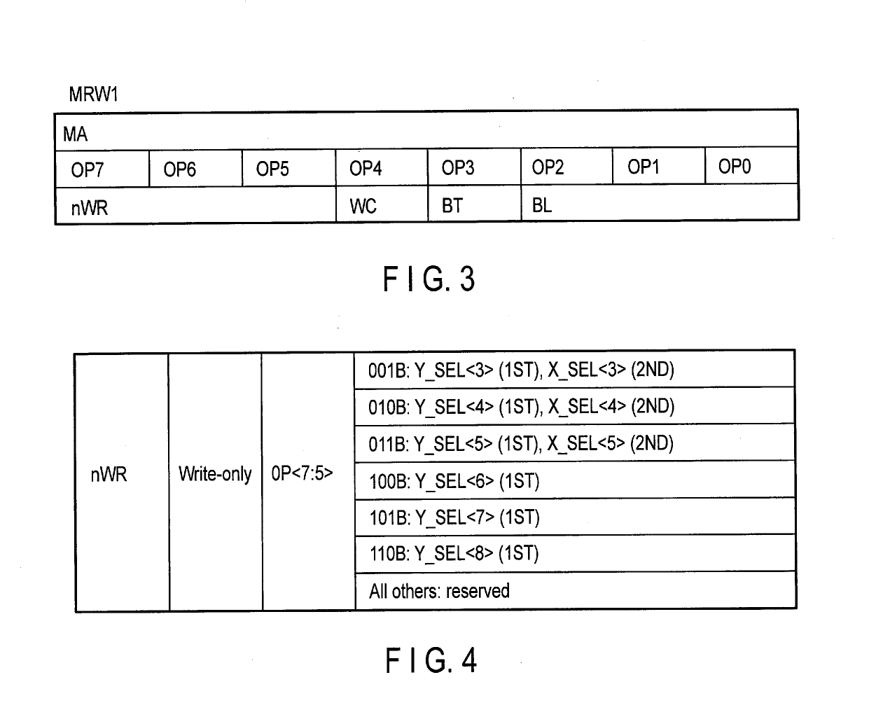

Next, referring to FIG. 3 and FIG. 4, a general description is given of a mode register write command MRW1 which is used at a time of controlling the mode register control circuit 28.

As illustrated in FIG. 3 and FIG. 4, the mode register write command MRW1 includes mode register assignment (MA) information which includes option information OP0 to OP7. Three bits are assigned to options OP<7:5>, and information (Y_SEL<8:3>/X_SEL<5:3>) for selecting a signal nWR, which is to be later, is defined as three-bit information.

When the mode register control circuit 28 successively receives commands MRW1, the mode register control circuit 28 selects Y_SEL<3>˜Y_SEL<8> (see (1ST) in the Figure) in a first input command MRW1, and selects X_SEL<3>˜X_SEL<5> (see (2ND) in the Figure) in a second input command MRW1.

<Mode Register Control Circuit>

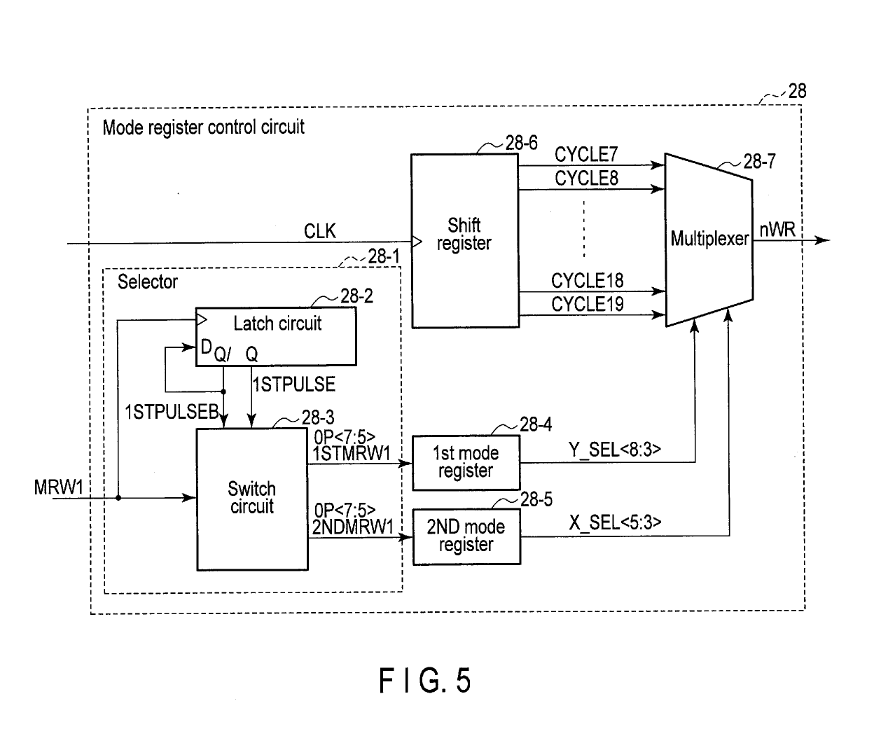

Next, referring to FIG. 5, a description is given of a configuration of the mode register control circuit 28 according to the first embodiment. The mode register control circuit 28 includes a selector 28-1, a first mode register 28-4, a second mode register 28-5, a shift register 28-6, and a multiplexer 28-7.

The selector 28-1 includes a latch circuit 28-2 and a switch circuit 28-3.

The latch circuit 28-2 receives, at a clock terminal thereof, a mode register write command MRW1 from the command/address latch circuit 24. An output terminal /Q of the latch circuit 28-2 is connected to an input terminal D thereof, and outputs a signal 1STPULSEB to the switch circuit 28-3. A 1STPULSE is output from an output terminal Q thereof to the switch circuit 28-3.

The switch circuit 28-3 receives the mode register write command MRW1, signal 1STPULSE and signal 1STPULSEB. Then, based on the signal 1STPULSE and signal 1STPULSEB, the switch circuit 28-3 outputs an input mode register write command MRW1, which has first been input, as a first mode register write command 1STMRW1 to the first mode register 28-4. In addition, based on the signal 1STPULSE and signal 1STPULSEB, the switch circuit 28-3 outputs a mode register write command MRW1, which has been input following the first input mode register write command MRW1, as a second mode register write command 2NDMRW1 to the second mode register 28-5.

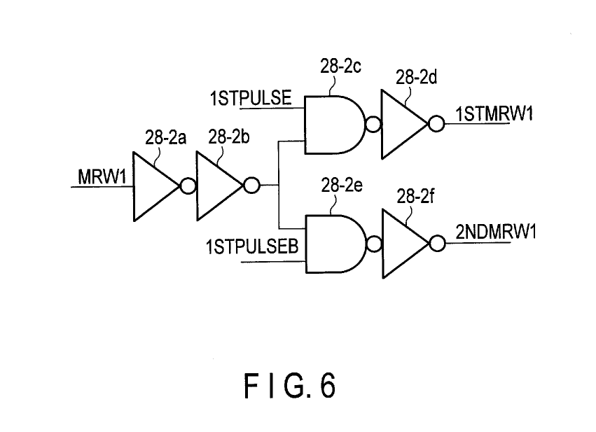

Referring now to FIG. 6, a concrete configuration example of the switch circuit 28-3 is described. As illustrated in FIG. 6, the switch circuit 28-3 includes, for example, inverter circuits 28-2a, 28-2b, 28-2d and 28-2f, and NAND gates 28-2c and 28-2e.

The inverter circuit 28-2a receives the mode register write command MRW1 from the command/address latch circuit 24. Then, an output signal of the inverter circuit 28-2a is input to one of input terminals of each of the NAND gates 28-2c and 28-2e via the inverter circuit 28-2b. The NAND gate 28-2c receives the signal 1STPULSE at the other of the input terminals thereof. Then, the NAND gate 28-2c supplies, as an arithmetic result between the received mode register write command MRW1 and signal 1STPULSE, a first mode register write command 1STMRW1 to the first mode register 28-4 via the inverter circuit 28-2d. The NAND gate 28-2e receives the signal 1STPULSEB at the other of the input terminals thereof. Then, the NAND gate 28-2e supplies, as an arithmetic result between the received mode register write command MRW1 and signal 1STPULSEB, a second mode register write command 2NDMRW1 to the second mode register 28-5 via the inverter circuit 28-2f.

As illustrated in FIG. 5, when the first mode register 28-4 is receiving the first mode register write command 1STMRW1, the first mode register 28-4 outputs, based on 3-bit nWR information (OP<7:5>(1ST)) which is included in the first mode register write command 1STMRW1, a corresponding signal Y_SEL<8:3> (Y_SEL<3>˜Y_SEL<8>) to the multiplexer 28-7.

When the second mode register 28-5 is receiving the second mode register write command 2NDMRW1, the second mode register 28-5 outputs, based on 3-bit nWR information (OP<7:5>(2ND)) which is included in the second mode register write command 2NDMRW1, a corresponding signal X_SEL<5:3> (X_SEL<3>-X_SEL<5>) to the multiplexer 28-7.

The shift register 28-6 receives the clock CLK from the clock generator 29, counts up the cycle of the clock (also referred to as “clock cycle” or “cycle”), and supplies, for example, CYCLE<7>˜CYCLE<19> to the multiplexer 28-7. Incidentally, in the present specification, when the cycle number is mentioned, the cycle number is expressed as “CYCLE<numeral>”, etc. In addition, 1 cycle=tWR/tCK (tCK: a time needed for 1 cycle).

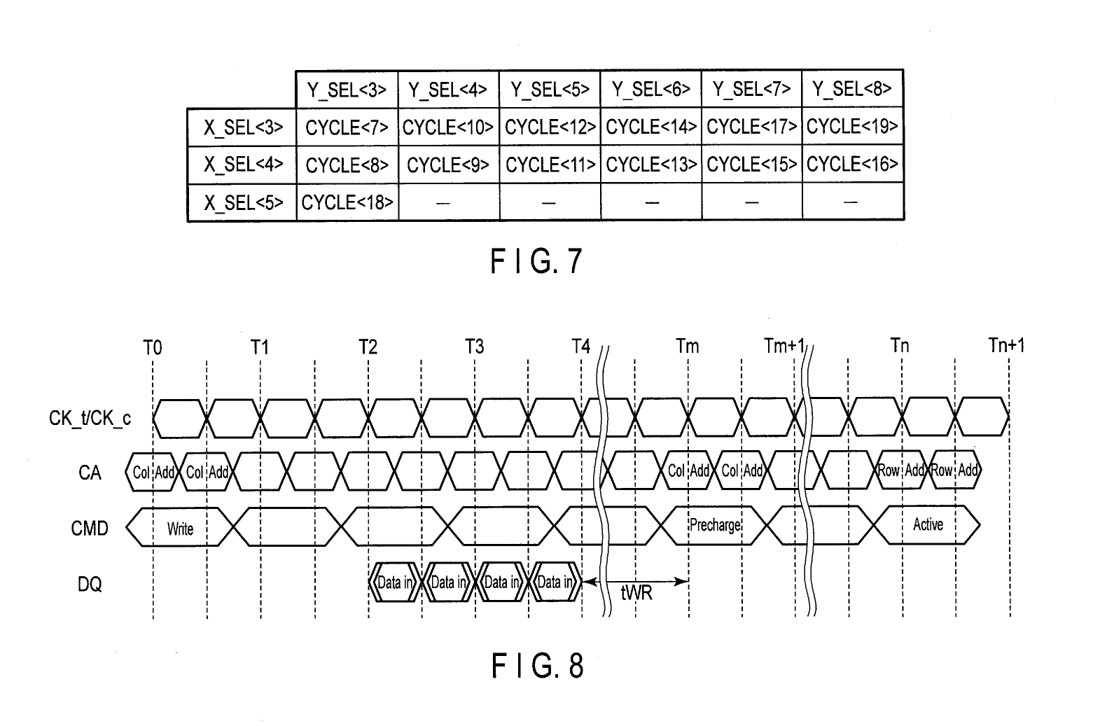

As illustrated in FIG. 5 and FIG. 7, the multiplexer 28-7 is configured to select, based on the received signal Y_SEL<8:3> and signal X_SEL<5:3>, the CYCLE<7>˜CYCLE<19>, and outputs the selected cycle as a signal nWR.

Specifically, for example, when the multiplexer 28-7 receives the signal Y_SEL<3> and signal X_SEL<3>, the multiplexer 28-7 selects CYCLE<7>. In addition, for example, when the multiplexer 28-7 receives the signal Y_SEL<4> and signal X_SEL<4>, the multiplexer 28-7 selects CYCLE<9>.

In the meantime, when the multiplexer 28-7 has not received the signal X_SEL<5:3> even after a predetermined period since the multiplexer 28-7 received the signal Y_SEL<8:3>, the multiplexer 28-7 handles the signal X_SEL<5:3> as the signal X_SEL<3>.

In addition, in the case where the mode register control circuit 28 receives not the second mode register write command, but a different command, after the reception of the first mode register write command, the multiplexer 28-7 handles the signal X_SEL<5:3> as the signal X_SEL<3>.

The signal nWR is supplied to the control circuit 25, and the control circuit 25 determines a write recovery time of the semiconductor memory device 10, based on the received signal nWR. Incidentally, nWR is a value defined by tWR/tCK (tCK: clock time), and is also referred to as “cycle number”.

Although FIG. 5 illustrates the mode register control circuit 28 which includes, as mode registers, only the first mode register 28-4 and second mode register 28-5 which are necessary for outputting the signal nWR, the configuration of the mode register control circuit 28 is not limited to this example. The mode register control circuit 28 may include mode registers other than the first mode register 28-4 and second mode register 28-5.

<Outline of the Operation of the Semiconductor Memory Device>

Next, a description is given of a basic signal nWR select operation of the semiconductor memory device 10 according to the first embodiment.

The host 13 issues a first MR (Mode register) command MRW1 to the peripheral circuit 12. This first mode register write command MRW1 includes at least 3-bit data for selecting Y_SEL<8:3>. Subsequently, the host 13 issues a second MR (Mode register) command MRW1 to the peripheral circuit 12. This second mode register write command MRW1 includes at least 3-bit data for selecting X_SEL<5:3>. The mode register control circuit 28 successively receives the first mode register write command MRW1 and the second mode register write command MRW1 from the host 13 via the command/address latch circuit 24.

As has been described above, the mode register control circuit 28 outputs the signal nWR (cycle number) to the control circuit 25, based on information relating to Y_SEL<8:3>, which is included in the first mode register write command MRW1, and information relating to X_SEL<5:3>, which is included in the second mode register write command MRW1.

Incidentally, the mode register write command MRW1 should be executed before an activate command (to be described later) is issued. If the activate command has been issued before the mode register write command MRW1 is issued, initialization (precharge) has to be executed before the mode register write command MRW1 is issued.

In addition, the mode register control circuit 28 uses the second mode register write command MRW1 with respect to information other than the information OP<7:5> relating to the signal nWR. It is thus desirable that the information of the second mode register write command MRW1 be identical to the information of the first mode register write command MRW1, with respect to the information other than the information relating to the signal nWR.

Next, referring to FIG. 8, a description is given of a basic write cycle of the semiconductor memory device 10 according to the first embodiment. Incidentally, the time in the semiconductor memory device 10 is controlled by a clock signal CK_t/CK_c which is generated by the clock generator 29.

In addition, in the write cycle of the semiconductor memory device 10 according to the present embodiment, a delay should be provided from the completion of the write operation of effective input data to the issuance of a precharge command. This delay varies depending on characteristics, etc. of the memory cells MC. This delay time is also called “write recovery time (tWR)”, and is a time from the completion of the write operation to the precharge.

Incidentally, the precharge is an operation for setting the memory cells MC in the initial state (precharge state). Specifically, all word lines, all bit lines and all source lines are rendered inactive.

“Active” is a command for executing a process of reading out data from the memory cell array 21, by activating a selected one of the plural word lines.

[Time Instant T0]

At time instant T0, a write command and a column address are issued by the control circuit 25.

[Time Instant T2]

At time instant T2, the memory core 11 executes a write operation by using data which has been received via the data latch circuit 27.

[Time Instant T4]

At time instant T4, if the write operation is completed, the control circuit 25 delays the issuance of the precharge command by at least the write recovery time tWR or more. The control circuit 25 executes the delay operation, based on the signal nWR (cycle number) which has been received from the mode register control circuit.

[Time Instant Tm]

At time instant Tm, the control circuit 25 executes precharge, after the passage of the signal nWR (cycle number) received from the mode register control circuit.

[Time Instant Tn]

At time instant Tn, the peripheral circuit 12 issues an activate command and a row address to the memory core 11. The activate operation is an operation for accessing a selected row.

In the manner described above, the write cycle of the semiconductor memory device 10 is executed.

### Advantageous Effects of the First Embodiment

According to the above-described embodiment, the semiconductor memory device includes the register control circuit configured to receive the first mode register write command MRW1 including information (Y_SEL<8:3>) for selecting the signal nWR relating to the control of the cycle of the clock from the completion of the write operation of data in the memory cell array 21 to the initialization of the memory cell array 21, and to output, when receiving, following the first mode register write command MRW1, the second mode register write command MRW1 including information (X_SEL<5:3>) for selecting the nWR, the signal nWR to the above-described control circuit, based on the Y_SEL<8:3> and X_SEL<5:3>. For example, in the case where the mode register control circuit is configured to select the signal nWR by only 3-bit information, only 6 kinds of signals nWR can be selected. However, the required signal nWR varies in accordance with the kind and capability of the memory cells. It is possible that the mode register control circuit is selectively fabricated in accordance with the respective memory cells, based on the kind and capability of the memory cells.

However, according to the mode register control circuit according to the above-described embodiment, since the signal nWR can be selected by 3-bit information×3-bit information, more signals nWR can flexibly be selected. Thus, there is no need to selectively fabricate the mode register control circuit in accordance with the memory cells. As a result, according to the above-described first embodiment, a high-quality semiconductor memory device can be provided.

### Second Embodiment

Next, a second embodiment is described. The second embodiment differs from the first embodiment in that the multiplexer of the mode register control circuit selects a signal nWR by using write latency/read latency information.

Incidentally, the basic configuration and basic operation of the semiconductor memory device according to the second embodiment are the same as those of the semiconductor memory device according to the above-described first embodiment. Accordingly, a description is omitted of matters which have been described in the above-described first embodiment and matters which can be easily guessed from the above-described first embodiment.

<Command MRW2>

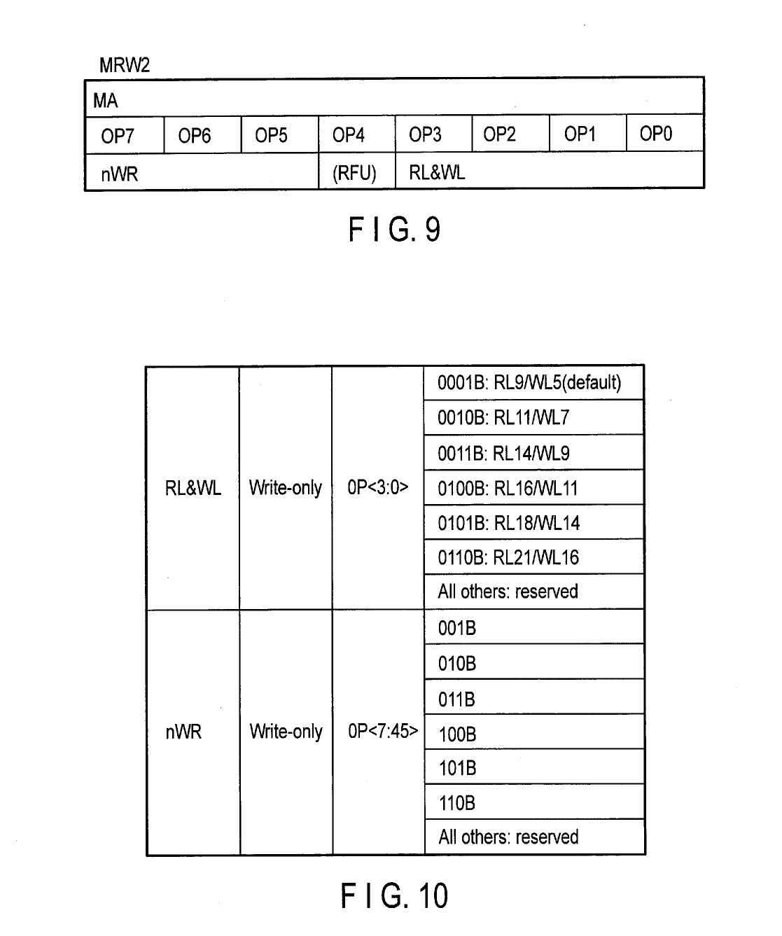

Next, referring to FIG. 9 and FIG. 10, a general description is given of a mode register write command MRW2 which is used at a time of controlling a mode register control circuit 28 according to the second embodiment.

As illustrated in FIG. 9 and FIG. 10, the mode register write command MRW2 includes mode register assignment (MA) information including option information OP0˜OP7. 4-bit read latency (RL) or write latency (WL) information is defined in the options OP0˜OP3 (OP<3:0>). Incidentally, the read latency is delay information which is used at a time of a read operation. The write latency is delay information which is used at a time of a write operation.

In addition, in the options OP5˜OP7 (OP<7:5>), information for selecting the nWR (to be described later) is defined as 3-bit information.

Incidentally, the mode register write command MRW2 should be executed before an activate command is issued.

If the activate command has been issued before the mode register write command MRW2 is issued, initialization (precharge) has to be executed before the mode register write command MRW2 is issued.

<Mode Register Control Circuit>

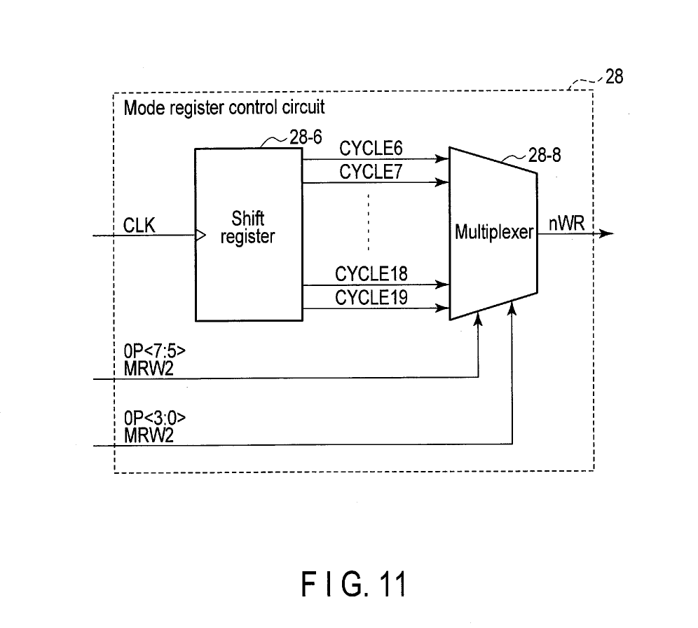

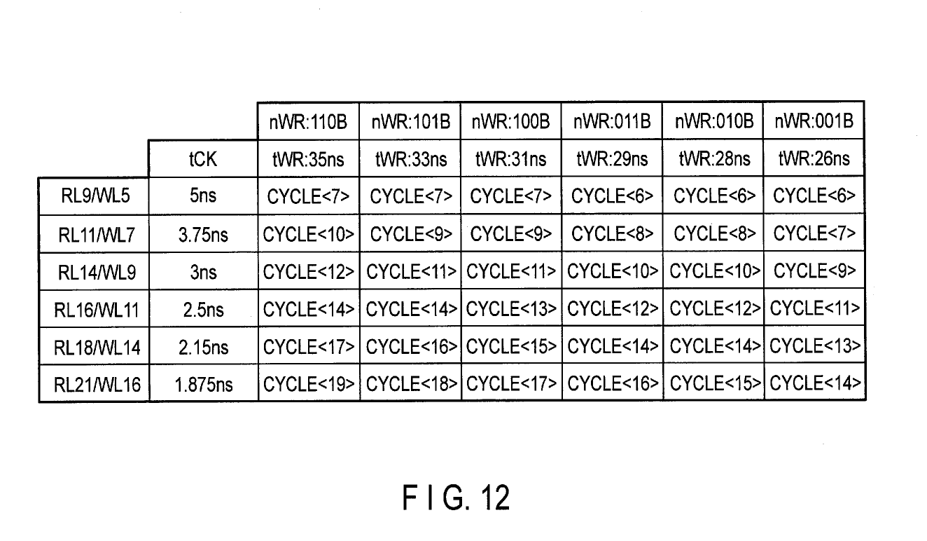

Next, referring to FIG. 11 and FIG. 12, a description is given of a configuration of the mode register control circuit 28 according to the second embodiment. As illustrated in FIG. 11, the mode register control circuit 28 includes a shift register 28-6 and a multiplexer 28-8.

As illustrated in FIG. 12, read latency/write latency is defined with respect to each time tCK. Specifically, when time tCK is 5 ns, read latency RL9 and write latency WL5 are set. When time tCK is 3.75 ns, read latency RL11 and write latency WL7 are set. When time tCK is 3 ns, read latency RL14 and write latency WL9 are set. Similarly, when time tCK is 2.5 ns, read latency RL16 and write latency WL11 are set. When time tCK is 2.15 ns, read latency RL18 and write latency WL14 are set. When time tCK is 1.875 ns, read latency RL21 and write latency WL16 are set.

In addition, information (OP<7:5>) for selecting the signal nWR is defined with respect to each time tWR. Specifically, when time tWR is 26 ns, 001B is set. When time tWR is 28 ns, 010B is set. When time tWR is 29 ns, 011B is set. In addition, when time tWR is 31 ns, 100B is set. When time tWR is 33 ns, 101B is set. When time tWR is 35 ns, 110B is set.

As illustrated in FIG. 11 and FIG. 12, the multiplexer 28-8 is configured to select CYCLE<6>˜CYCLE<19>, based on the received mode register write command MRW2 (OP<3:0> and OP<7:5>), and outputs the selected cycle as the signal nWR. Specifically, for example, the multiplexer 28-8 selects CYCLE<6>, when information OP<3:0> is “0001B” and information OP<7:5> is “001B” in the received mode register write command MRW2. In addition, for example, the multiplexer 28-8 selects CYCLE<19>, when information OP<3:0> is “0110B” and information OP<7:5> is “110B” in the received mode register write command MRW2.

### Advantageous Effects of the Second Embodiment

According to the above-described embodiment, the information which is used at the time of read latency/write latency is also used at the time of cycle selection. Thereby, with one-time input of the mode register write command MRW2, the same advantageous effects as described in connection with the first embodiment can be obtained.

### Modifications, Etc.

In the meantime, according to the above-described first embodiment, such a configuration is adopted that signals Y_SEL<3>˜Y_SEL<8> are stored in the first mode register 28-4, and the signals Y_SEL<3>˜Y_SEL<8> are output, based on the received command OPW_1ST (001B, 010B, 011B, 100B, 101B, 110B). In addition, such a configuration is adopted that signals X_SEL<3>˜X_SEL<5> are stored in the second mode register 28-5, and the signals X_SEL<3>˜X_SEL<5> are output, based on the received command OPW_2ND (001B, 010B, 011B). However, the first embodiment is not limited to these examples, and the signals, which are stored in the first mode register 28-4 and second mode register 28-5, can be various changed.

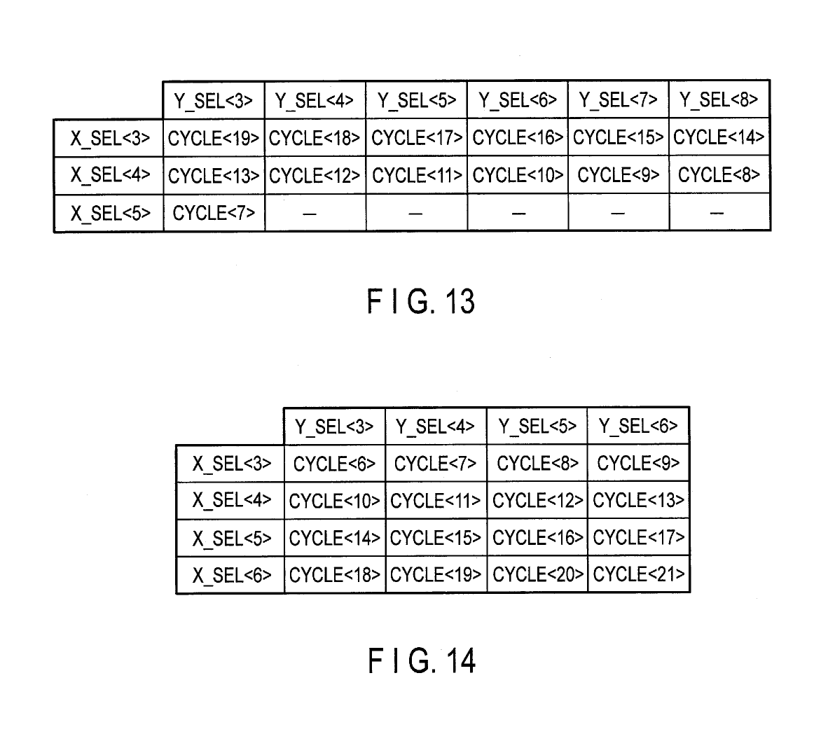

In addition, in the above-described first embodiment, the description has been given of the configuration in which the multiplexer 28-7 outputs the cycle number, as illustrated in FIG. 7, based on the signal Y_SEL<8:3> and signal X_SEL<5:3>. However, this is merely an example, and the first embodiment is not limited to this example. For example, the multiplexer 28-7 may be configured to output the cycle number, as illustrated in FIG. 13, based on the signal Y_SEL<8:3> and signal X_SEL<5:3>. In this manner, it should suffice if the multiplexer 28-7 is configured to output the cycle number, based on the signal Y_SEL<8:3> and signal X_SEL<5:3>, and the cycle numbers, etc., which are output, may be properly changed.

Furthermore, according to the above-described first embodiment, as illustrated in FIG. 14, the multiplexer 28-7 may be configured to output the cycle number, as illustrated in FIG. 14, based on signal Y_SEL<6:3> and signal X_SEL<6:3>.

Besides, according to the first embodiment, the shift register 28-6 is configured to output CYCLE<7>˜CYCLE<19>, and, according to the second embodiment, the shift register 28-6 is configured to output CYCLE<6>˜CYCLE<19>. However, the embodiments are not limited to these examples, and various changes may be made.

In each of the above-described embodiments, the MRAM using the magnetoresistive effect element has been described as the semiconductor memory device by way of example. However, the embodiments are not limited to this example, and the embodiments are applicable to various kinds of semiconductor memory devices, regardless of volatile memories or nonvolatile memories. In addition, the embodiments are applicable to resistance change memories of the same kind as the MRAM, for example, a FeRAM (Ferroelectric random access memory), a PCRAM (phase change random access memory), or a ReRAM (resistive random access memory).

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array including a plurality of memory cells configured to be able to store data;
a control circuit which controls a write operation of data in the memory cell array, and an initialization operation of the memory cell array; and
a register control circuit which receives a first command including second information for selecting first information relating to control of a cycle of a clock from completion of the write operation of data in the memory cell array to initialization of the memory cell array, and outputs, when receiving, following the first command, a second command including third information for selecting the first information, the first information to the control circuit, based on the second information and the third information.

2. The device of claim 1, wherein the register control circuit comprises:
a first register which stores fourth information corresponding to the second information; and
a second register which stores fifth information corresponding to the third information.

3. The device of claim 2, wherein the register control circuit further comprises a selector which discriminates between the first command the second command.

4. The device of claim 3, wherein the register control circuit further comprises a third register which generates a plurality of pieces of the first information.

5. The device of claim 4, wherein the register control circuit further comprises a multiplexer which selects and outputs one of the plurality of pieces of the first information, which are supplied from the third register, based on the fourth information supplied from the first register and the fifth information supplied from the second register.

6. The device of claim 1, wherein, in the first command and the second command, information excluding at least the second information and the third information is identical information.

7. The device of claim 1, wherein when the register control circuit successively receives the first command and the second command, information excluding the second information in the first command is overwritten by information of the second command.

8. The device of claim 1, wherein the memory cell array includes a plurality of rows and a plurality of columns, and
the memory cells are provided at intersections between the plurality of rows and the plurality of columns.

9. The device of claim 8, wherein when an activate command by which a predetermined row of the plurality of rows is selected has been input, the register control circuit does not output the first information until the memory cell array is initialized.

10. The device of claim 1, wherein the first information is a cycle number of the clock.

11. The device of claim 1, wherein the memory cell includes a variable resistance element.

12. The device of claim 1, wherein the memory cell is any one of an MRAM (Magnetic Random Access Memory), an FeRAM (Ferroelectric random access memory), a PCRAM (phase change random access memory) and an ReRAM (resistive random access memory).

13. A semiconductor memory device comprising:
a memory cell array including a plurality of memory cells;
a control circuit which controls a write operation, a read operation, and initialization of the memory cell array; and
a register control circuit which selects, when receiving a first command including second information for selecting first information relating to control of a cycle of a clock from completion of the write operation to the initialization of the memory cell array, and third information which is used at a time of the write operation or at a time of the read operation, one of a plurality of pieces of the first information, based on the second information and the third information, and supplies the first information to the control circuit.

14. The device of claim 13, wherein the register control circuit comprises a first register which generates a plurality of pieces of the first information.

15. The device of claim 14, wherein the register control circuit further comprises a multiplexer which selects and outputs one of the plurality of pieces of the first information, which are supplied from the first register, based on the second information and the third information.

16. The device of claim 13, wherein the memory cell array includes a plurality of rows and a plurality of columns, and
the memory cells are provided at intersections between the plurality of rows and the plurality of columns.

17. The device of claim 16, wherein when an activate command by which a predetermined row of the plurality of rows is selected has been input, the register control circuit does not output the first information until the memory cell array is initialized.

18. The device of claim 13, wherein the first information is a cycle number of the clock.

19. The device of claim 13, wherein the memory cell includes a variable resistance element.

20. The device of claim 13, wherein the memory cell is any one of an MRAM (Magnetic Random Access Memory), an FeRAM (Ferroelectric random access memory), a PCRAM (phase change random access memory) and an ReRAM (resistive random access memory).
